(19) United States
(12) Patent Application Publication
(10) Pub. No.: US 2026/0047367 A1
(43) Pub. Date: Feb. 12, 2026

(54) SEMICONDUCTOR WAFER AND METHOD FOR FORMING THE SAME

(71) Applicant: Hon Young Semiconductor Corporation, Hsinchu City (TW)

(72) Inventors: Chin-Hung CHEN, Hsinchu City (TW); Hung-Hsin YEN, Hsinchu City (TW); Yi-Jen LIN, Hsinchu City (TW)

(21) Appl. No.: 18/822,473

(22) Filed: Sep. 3, 2024

(30) Foreign Application Priority Data
Aug. 6, 2024 (TW) 113129461

(51) Int. Cl. H01L 21/04; H01L 29/16; H01L 29/167

(52) U.S. Cl. CPC H01L 21/0465; H01L 21/047; H10D 62/834; H10D 62/8325

(57) ABSTRACT

A method for forming a semiconductor wafer includes providing a substrate wafer, in which the substrate wafer has a bow value that is non-zero and has a first portion, the first portion has a first surface and a second surface opposite to the first surface, and the first surface is concave. The method further includes performing a first ion implantation process to the substrate wafer, such that the first surface of the first portion has a first implantation region, and the bow value of the substrate wafer is closer to zero after performing the first ion implantation process than before performing the first ion implantation process. The method further includes depositing an epitaxial layer on the substrate wafer after performing the first ion implantation process.

CROSS-REFERENCE TO RELATED APPLICATION

This application claims priority to Taiwan Application Serial Number 113129461, filed Aug. 6, 2024, which is herein incorporated by reference in its entirety.

### BACKGROUND

### Field of Disclosure

The present disclosure relates to a semiconductor wafer and a method for forming the same.

### Description of Related Art

During the fabrication of semiconductor devices, residual stress in the substrate wafer may cause bow to the substrate wafer, leading the substrate wafer to crack in subsequent processes. In addition, as the desired breakdown voltage of the semiconductor devices increases, the doping concentration of the epitaxial layer decreases and the thickness of the epitaxial layer increases. However, if such epitaxial layer is deposited directly on a substrate wafer having a non-zero bow value, stress accumulation may occur, resulting in more evident bow.

Accordingly, how to provide a semiconductor wafer and a method for forming a semiconductor wafer to solve the aforementioned problems becomes an important issue to be solved by those in the industry.

### SUMMARY

According to an embodiment of the disclosure, a method for forming a semiconductor wafer includes providing a substrate wafer, in which the substrate wafer has a bow value that is non-zero and has a first portion, the first portion has a first surface and a second surface opposite to the first surface, and the first surface is concave. The method further includes performing a first ion implantation process to the substrate wafer, such that the first surface of the first portion has a first implantation region, and the bow value of the substrate wafer is closer to zero after performing the first ion implantation process than before performing the first ion implantation process. The method further includes depositing an epitaxial layer on the substrate wafer after performing the first ion implantation process.

According to an embodiment of the disclosure, a semiconductor wafer includes a substrate wafer and an epitaxial layer. The substrate wafer has a first surface and a second surface opposite to the first surface. The first surface has a first implantation region. A first implantation dose of the first implantation region is between about 1×10¹⁰ #/cm² and about 5×10¹⁶ #/cm². The epitaxial layer is over the substrate wafer.

Accordingly, in the semiconductor wafer and the method for forming the semiconductor wafer of some embodiments of the present disclosure, the substrate wafer is implanted before depositing the epitaxial layer, and the stress introduced by the ion implantation eliminates the residual stress of the substrate wafer generated by previous processes. Therefore, the bow value of the substrate wafer may become closer to zero, thereby reducing the risk of cracking or further bowing of the substrate wafer in subsequent processes and improving the yield of the substrate wafer.

### BRIEF DESCRIPTION OF THE DRAWINGS

The disclosure can be more fully understood by reading the following detailed description of the embodiment, with reference made to the accompanying drawings as follows:

FIG. 1 illustrates a cross-sectional view and a top view of a substrate wafer according to some embodiments of the present disclosure;

FIG. 2 and FIG. 3 illustrate cross-sectional views of intermediate stages of a method for forming a semiconductor wafer according to some embodiments of the present disclosure;

FIG. 4 and FIG. 5 illustrate cross-sectional views of intermediate stages of a method for forming a semiconductor wafer according to some other embodiments of the present disclosure; and

FIG. 6 and FIG. 7 illustrate cross-sectional views of intermediate stages of a method for forming a semiconductor wafer according to yet some other embodiments of the present disclosure.

### DETAILED DESCRIPTION

In the fabrication of semiconductor devices, seed crystals are used to grow an ingot through physical vapor transport (PVT) or high temperature chemical vapor deposition (HTCVD). Then, the ingot is sliced up and forms substrate wafers by, for example, wire cutting. During the process of crystal growth or slicing, stress may accumulate in the substrate wafers, causing the bow of the substrate wafers. This may cause the substrate wafers to crack during subsequent processes, especially during processes such as heat treatment, which may cause thermal shock to the substrate wafers. In addition, when the desired breakdown voltage of the semiconductor devices is relatively high, an epitaxial layer with a relatively low doping concentration and a relatively large thickness is required. In such case, if the epitaxial layer is directly deposited on the bowed substrate wafer, stress accumulation may be induced, leading to a more evident wafer bow. Therefore, the present disclosure aims to provide a method for forming a semiconductor wafer to reduce the bow of the substrate wafer.

First, the method includes providing a substrate wafer. Next, the method includes determining whether the substrate wafer is bowed. For example, measuring the bow value of the substrate wafer.

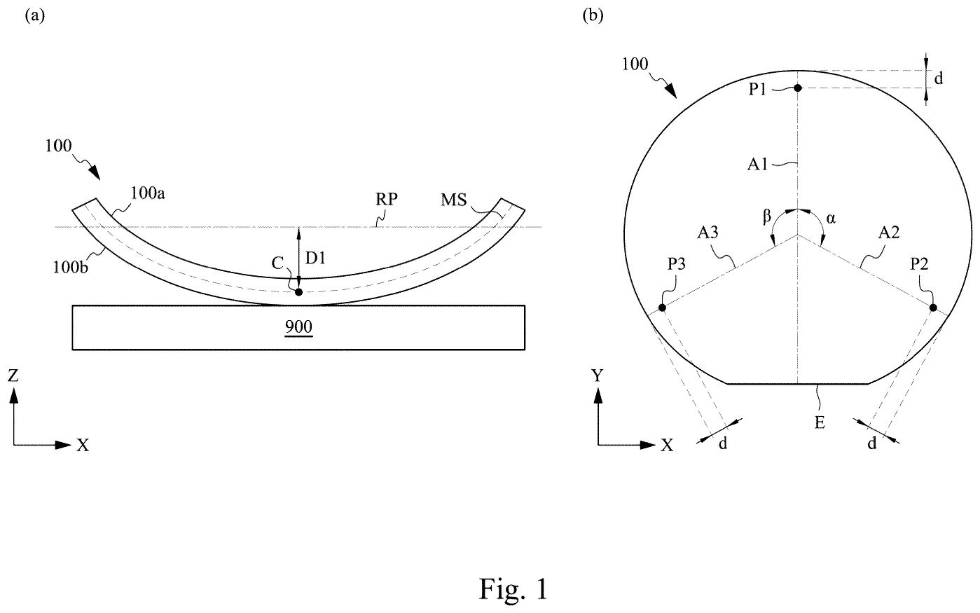

The following describes the definition of bow value in the present disclosure with reference to FIG. 1, taking the substrate wafer 100 as an example. Part (a) of FIG. 1 is a cross-sectional view of the substrate wafer 100 to be measured placed on a stage 900 according to some embodiments of the present disclosure, and part (b) of FIG. 1 is a top view of the substrate wafer 100 to be measured. Direction X, direction Y, and direction Z are marked as in the figures.

In this disclosure, the bow value is defined as a distance between a center point C of a median surface MS of the substrate wafer 100 and a reference plane RP of the substrate wafer 100 along a direction substantially perpendicular to the stage 900 when the substrate wafer 100 is placed with the front side 100a (i.e., the crystal face of the substrate wafer 100) of the substrate wafer 100 facing upward and is free, un-clamped on the stage 900. For example, as shown in FIG. 1, the front side 100a of the substrate wafer 100 faces upward and the front side 100a is concave. In this case, the bow value of the substrate wafer 100 is equal to the distance D1 along the direction Z shown in FIG. 1. In the case of part (a) of FIG. 1, the front side 100a appears concave due to tensile stress, and the bow value is negative. On the contrary, if the front side 100a of the substrate wafer 100 is convex due to compressive stress, the bow value is positive.

It should be noted that the median surface MS is an imaginary surface whose distance to the front side 100a is the same as its distance to the back side 100b at every location of the substrate wafer 100 (i.e., the median surface MS divides the substrate wafer 100 into upper and lower halves), and the reference plane RP is an imaginary plane formed by a point P1, a point P2, and a point P3, as shown in part (b) of FIG. 1. The point P1 is on an axis A1 and has a distance d along the axis A1 from an edge of the substrate wafer 100. The point P2 is on an axis A2 and has a distance d along the axis A2 from the edge of the substrate wafer 100. The point P3 is on an axis A3 and has a distance d along the axis A3 from the edge of the substrate wafer 100. The axis A1 is a central axis perpendicular to a flat edge E of the substrate wafer 100. An angle α between the axis A2 and the axis A1 is about 120 degrees, and an angle β between the axis A3 and the axis A1 is about 120 degrees. In some embodiments, the distance d is about 6 mm.

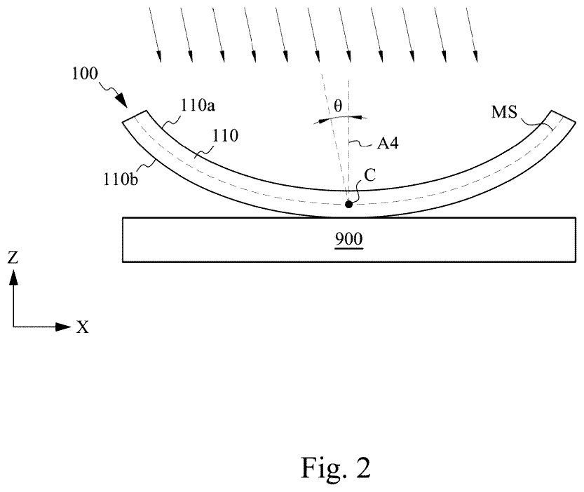

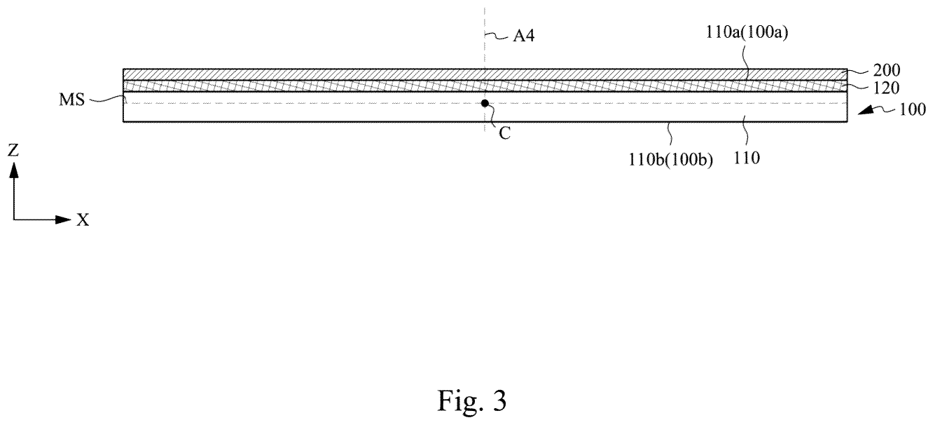

Reference is made to FIG. 2 and FIG. 3. FIG. 2 and FIG. 3 illustrate cross-sectional views of intermediate stages of a method for forming a semiconductor wafer according to some embodiments of the present disclosure. In the method of the present disclosure, when it is determined that the substrate wafer 100 has a non-zero bow value, an ion implantation process is performed to the concave surface of the substrate wafer 100. Thereby, stress that is in an opposite direction to the residual stress in the substrate wafer 100 is introduced, making the bow value of the substrate wafer 100 closer to zero. As a result, the substrate wafer 100 becomes flatter.

In greater detail, as shown in FIG. 2, the substrate wafer 100 has a first portion 110 that is upwardly concave. The first portion 110 has a first surface 110a and a second surface 110b opposite to the first surface 110a. The first surface 110a is a concave surface. Therefore, a first ion implantation process is performed to the first surface 110a of the first portion 110.

In some embodiments, an implant species in the first ion implantation process may include at least one of a titanium ion, a nickel ion, an iron ion, a zirconium ion, a tin ion, a magnesium ion, a cobalt ion, an arsenic ion, a zinc ion, an indium ion, an antimony ion, a germanium ion, a hydrogen ion, a helium ion, an oxygen ion, an aluminum ion, a boron ion, a nitrogen ion, a phosphorus ion, a silicon ion, and a carbon ion, in order to introduce compressive stress to the first surface 110a. The implant species may be selected based on the value of bow.

In some embodiments, the first ion implantation process is performed at a tilt angle θ. The tilt angle θ is between an incident direction of the ion beam and an axis A4 passing through the center point C and perpendicular to the median surface MS. In some embodiments, the tilt angle θ is between about 0 degree and about 45 degrees. When the tilt angle θ is about 0 degree, the ion beam is incident substantially perpendicular to the substrate wafer 100.

In some embodiments, when performing the first ion implantation process, the stage 900 may drive the substrate wafer 100 to rotate. The twist angle for such rotation is between about 0 degree and about 360 degrees. When the twist angle is about 0 degree, the stage 900 remains stationary. When the twist angle is about 360 degrees, the stage 900 rotates once.

In some embodiments, the tilt angle θ and the twist angle may be adjusted to utilize the channeling effect for ion implantation. For example, the tilt angle θ is set to be about 4 degrees and the twist angle is set to be about 270 degrees.

In some embodiments, an implantation energy (i.e., ion beam energy) of the first ion implantation process is between about 1 keV and about 5 MeV. In some embodiments, an implantation dose of the first ion implantation process is between about 1×10¹⁰ #/cm² and about 5×10¹⁶ #/cm². In some embodiments, a process temperature of the first ion implantation process is between about 25° C. and about 650° C.

Next, as shown in FIG. 3, the first ion implantation process is performed so that the first surface 110a has a first implantation region 120. Due to the stress exerted by the implanted ions, the bow value of the substrate wafer 100 becomes closer to zero after performing the first ion implantation process than before performing the first ion implantation process. In other words, an absolute value of the bow value of the substrate wafer 100 decreases.

In some embodiments, the implantation dose may gradually change over the first implantation region 120. For example, implantation doses at different locations in the first implantation region 120 vary with their distances from the center point C. For example, the first implantation region 120 has an implantation dose of about 1×10¹⁰ #/cm² above the center point C and has an implantation dose of about 2×10¹⁰ #/cm² at an edge of the first implantation region 120.

After performing the first ion implantation process, the method further includes depositing an epitaxial layer 200 on the substrate wafer 100, such as through chemical vapor deposition (CVD), to form a semiconductor wafer for subsequent processing to form semiconductor devices. To be more specific, the epitaxial layer 200 is deposited on the front side 100a of the substrate wafer 100. In some embodiments, the front side 100a is the crystal face and/or the silicon face (Si-face) of a silicon carbide wafer, and the back side 100b is the carbon face (C-face) of the silicon carbide wafer. In some embodiments, as shown in FIG. 3, the first surface 110a of the first portion 110 is at least a part of the front side 100a of the substrate wafer 100. In this way, the epitaxial layer 200 is in contact with the first implantation region 120 of the first surface 110a and is away from the second surface 110b, as shown in FIG. 3.

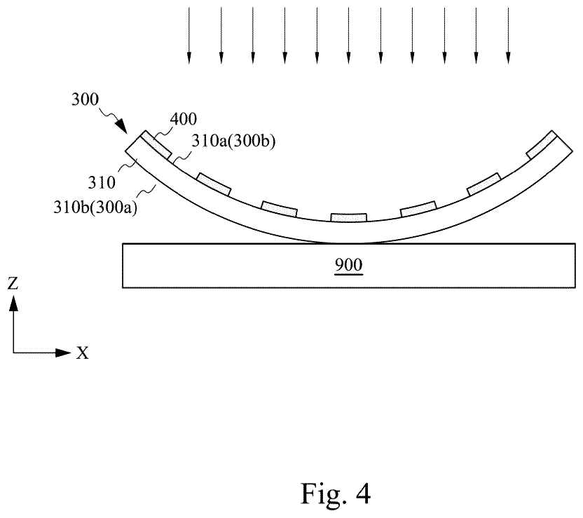

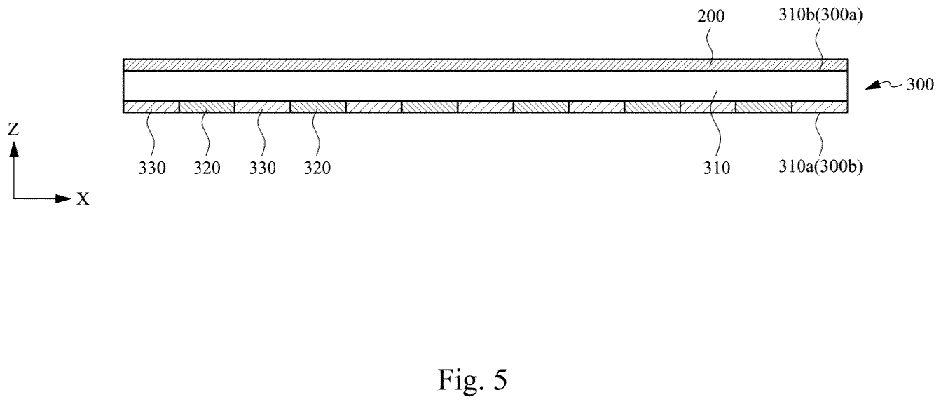

Reference is made to FIG. 4 and FIG. 5. FIG. 4 and FIG. 5 are cross-sectional views of intermediate stages of a method for forming a semiconductor wafer according to some other embodiments of the present disclosure. In such embodiments, a substrate wafer 300 with a positive bow value is provided. That is, the front side 300a (e.g., the crystal face) of the substrate wafer 300 is convex, while the back side 300b is concave. In this case, an ion implantation process is performed to the concave back side 300b, introducing compressive stress to bring the bow value of the substrate wafer 300 closer to zero.

In greater detail, as shown in FIG. 4, the substrate wafer 300 has a first portion 310. The first portion 310 has a first surface 310a and a second surface 310b opposite to the first surface 310a. The first surface 310a is a concave surface. In such embodiments, the concave first surface 310a is at least a part of the back side 300b of the substrate wafer 300, and the second surface 310b is at least a part of the front side 300a of the substrate wafer 300. After measuring the bow value of the substrate wafer 300, the substrate wafer 300 is placed on the stage 900 with the concave first surface 310a facing upward, as shown in FIG. 4, to facilitate ion implantation.

Then, a mask layer 400 is deposited on the first surface 310a. In some implementations, the mask layer 400 may include an oxide or photoresist material. In some embodiments, the mask layer 400 may include amorphous or polycrystalline materials. In some embodiments, the mask layer 400 has a thickness between about 0.1 microns and about 4 microns. In some embodiments, the mask layer 400 is formed using low pressure chemical vapor deposition (LPCVD), plasma-enhanced chemical vapor deposition (PECVD), or sputtering. In some embodiments, the mask layer 400 is patterned to form a pattern as shown in FIG. 4. In some embodiments, the mask layer 400 may fully cover the first surface 310a without patterning, but the present disclosure is not limited thereto.

Next, a first ion implantation process is performed to the first surface 310a through the mask layer 400. Since the mask layer 400 includes amorphous or polycrystalline materials, ions may be scattered or diffused when passing through the mask layer 400, thereby achieving a more uniform implantation.

As shown in FIG. 5, the first ion implantation process is performed such that the first surface 310a has a plurality of first implantation regions 320, corresponding to portions of the first surface 310a that are not covered by the mask layer 400. In some embodiments, the implantation energy of the first ion implantation process is sufficient to drive ions through the mask layer 400 and implant ions into portions of the first surface 310a that are covered by the mask layer 400, so that the first surface 310a has a plurality of second implantation regions 330. As shown in FIG. 5, the first implantation regions 320 and the second implantation regions 330 are alternately arranged, and an implantation dose of each of the first implantation regions 320 is greater than an implantation dose of each of the second implantation regions 330. Similarly, the implantation dose of each of the first implantation regions 320 and the implantation dose of each of the second implantation regions 330 are between about 1×10¹⁰ #/cm² and 5×10¹⁶ #/cm². For example, each of the first implantation regions 320 has an implantation dose of about 2×10¹⁰ #/cm², and each of the second implantation regions 330 has an implantation dose of about 1×10¹⁰ #/cm².

In some embodiments, the implantation energy of ions is not sufficient for the ions to pass through the mask layer 400. Therefore, the portions of the first surface 310a that are covered by the mask layer 400 remain unimplanted. That is, the implantation dose in each of the regions 330 is substantially zero. In this case, the mask layer 400 can be used to define regions that do not require ion implantation.

In some embodiments, the method may include removing the mask layer 400 after the first ion implantation process is completed.

Then, the epitaxial layer 200 is deposited on the front side 300a of the substrate wafer 300. As aforementioned, the second surface 310b of the first portion 310 is at least a part of the front side 300a of the substrate wafer 300. Therefore, the method may require that the second surface 310b be turned upward and then the epitaxial layer 200 be deposited on the second surface 310b. As such, the epitaxial layer 200 is in contact with the second surface 310b and is away from the regions 320 and the regions 330 of the first surface 310a.

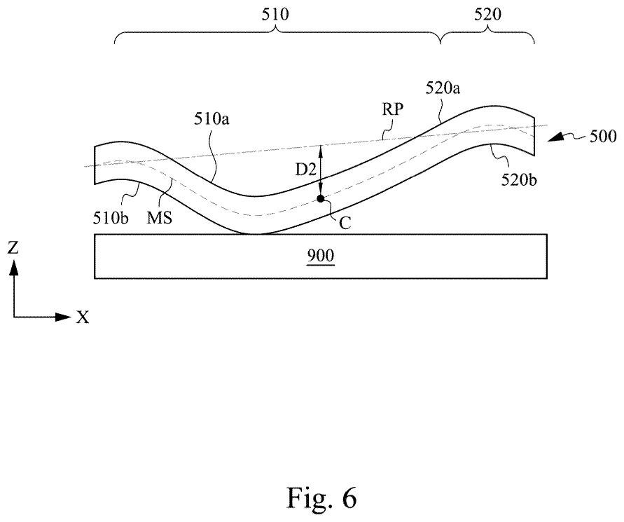

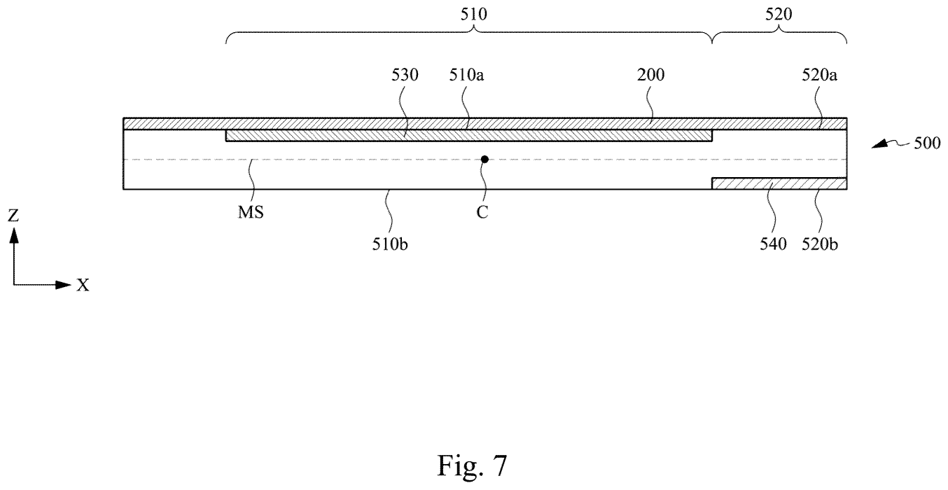

Reference is made to FIG. 6 and FIG. 7. FIG. 6 and FIG. 7 are cross-sectional views of intermediate stages of a method for forming a semiconductor wafer according to yet some other embodiments of the present disclosure. In these embodiments, a substrate wafer 500 with a bow value equivalent to a distance D2 shown in FIG. 6 is provided. As shown in FIG. 6, the substrate wafer 500 has a first portion 510 and a second portion 520. The first portion 510 has a first surface 510a and a second surface 510b opposite to the first surface 510a. The first surface 510a is concave and placed upward. The second portion 520 has a third surface 520a and a fourth surface 520b opposite to the third surface 520a. The fourth surface 520b is concave and placed downward. The first surface 510a is adjacent to the third surface 520a, and the second surface 510b is adjacent to the fourth surface 520b.

Similarly, a first ion implantation process is performed to the first surface 510a of the first portion 510. After performing the first ion implantation process, the bow value of the substrate wafer 500 is closer to zero than it would be before performing the first ion implantation process. Next, a second ion implantation process is performed to the fourth surface 520b of the second portion 520. After performing the second ion implantation process, the bow value of the substrate wafer 500 is closer to zero than before performing the second ion implantation process. In some embodiments, an implant species of the first ion implantation process and an implant species of the second ion implantation process may respectively include at least one of aluminum ions, boron ions, nitrogen ions, phosphorus ions, silicon ions, and carbon ions. In some embodiments, the implant species in the first ion implantation process may be different from the implant species in the second ion implantation process.

As shown in FIG. 7, after performing the first ion implantation process and the second ion implantation process, the first surface 510a of the first portion 510 has a first implantation region 530, and the fourth surface 520b of the second portion 520 has a second implantation region 540. In some embodiments, an implantation dose of the first implantation region 530 and an implantation dose of the second implantation region 540 are between about 1×10¹⁰ #/cm² and about 5×10¹⁶ #/cm². In some embodiments, the implantation dose of the first implantation region 530 may be different from the implanted dose of the second implantation region 540.

In some embodiments, the first surface 510a of the first portion 510 and the third surface 520a of the second portion 520 are part of the crystal face (i.e., the front side) of the substrate wafer 500, and the second surface 510b of the first portion 510 and the fourth surface 520b of the second portion 520 are part of the back side of the substrate wafer 500. Therefore, the first implantation region 530 and the second implantation region 540 are on opposite sides of the substrate wafer 500, respectively.

Similarly, the epitaxial layer 200 is deposited on the crystal face of the substrate wafer 500. Therefore, the epitaxial layer 200 is in contact with the first implantation region 530 of the first surface 510a and is away from the second implantation region 540 of the fourth surface 520b.

Accordingly, in the semiconductor wafer and the method for forming the semiconductor wafer of some embodiments of the present disclosure, the substrate wafer is implanted before depositing the epitaxial layer, and the stress introduced by the ion implantation eliminates the residual stress of the substrate wafer generated by previous processes. Therefore, the bow value of the substrate wafer may become closer to zero, thereby reducing the risk of cracking or further bowing of the substrate wafer in subsequent processes and improving the yield of the substrate wafer.

What is claimed is:

1. A method for forming a semiconductor wafer, comprising:
providing a substrate wafer, wherein the substrate wafer has a bow value that is non-zero and has a first portion, the first portion has a first surface and a second surface opposite to the first surface, and the first surface is concave;
performing a first ion implantation process to the substrate wafer, such that the first surface of the first portion has a first implantation region, and the bow value of the substrate wafer is closer to zero after performing the first ion implantation process than before performing the first ion implantation process; and
after performing the first ion implantation process, depositing an epitaxial layer on the substrate wafer.

2. The method of claim 1, wherein the epitaxial layer is in contact with the first surface of the first portion.

3. The method of claim 1, wherein the epitaxial layer is in contact with the second surface of the first portion and is away from the first implantation region.

4. The method of claim 1, wherein an implant species in the first implantation region comprises at least one of a titanium ion, a nickel ion, an iron ion, a zirconium ion, a tin ion, a magnesium ion, a cobalt ion, an arsenic ion, a zinc ion, an indium ion, an antimony ion, a germanium ion, a hydrogen ion, a helium ion, an oxygen ion, an aluminum ion, a boron ion, a nitrogen ion, a phosphorus ion, a silicon ion, and a carbon ion.

5. The method of claim 1, wherein the first ion implantation process is performed at a tilt angle and a twist angle, wherein the tilt angle is between about 0 degree and about 45 degrees, and the twist angle is between about 0 degree and about 360 degrees.

6. The method of claim 1, further comprising depositing a mask layer on the first surface, wherein the first ion implantation process is performed through the mask layer.

7. The method of claim 6, wherein the first ion implantation process is performed through the mask layer, so that the first surface of the first portion has the first implantation region and a second implantation region, wherein a first implantation dose of the first implantation region is different from a second implantation dose of the second implantation region, and the first implantation dose of the first implantation region and the second implantation dose of the second implantation region are between about 1×10¹⁰ #/cm² and about 5×10¹⁶ #/cm².

8. The method of claim 1, wherein before performing the first ion implantation process, the substrate wafer further has a second portion, the second portion has a third surface and a fourth surface opposite to the third surface, the third surface is adjacent to the first surface, the fourth surface is adjacent to the second surface, and the fourth surface is concave.

9. The method of claim 8, further comprising:
performing a second ion implantation process, such that the fourth surface of the second portion has a second implantation region, and the bow value of the substrate wafer is closer to zero after performing the second ion implantation process than before performing the second ion implantation process.

10. The method of claim 9, wherein an implant species in the first implantation region is different from an implant species in the second implantation region.

11. The method of claim 9, wherein a first implantation dose of the first implantation region is different from a second implantation dose of the second implantation region, and the first implantation dose of the first implantation region and the second implantation dose of the second implantation region are between about 1×10¹⁰ #/cm² and about 5×10¹⁶ #/cm².

12. A semiconductor wafer, comprising:
a substrate wafer having a first surface and a second surface opposite to the first surface, the first surface has a first implantation region, and a first implantation dose of the first implantation region is between about 1×10¹⁰ #/cm² and about 5×10¹⁶ #/cm²; and
an epitaxial layer over the substrate wafer.

13. The semiconductor wafer of claim 12, wherein the epitaxial layer is in contact with the first surface of the substrate wafer.

14. The semiconductor wafer of claim 12, wherein the epitaxial layer is in contact with the second surface of the substrate wafer and is away from the first implantation region.

15. The semiconductor wafer of claim 12, wherein the first surface has a second implantation region, a second implantation dose of the second implantation region is between about 1×10¹⁰ #/cm² and about 5×10¹⁶ #/cm², and the second implantation dose is different from the first implantation dose.

16. The semiconductor wafer of claim 12, wherein the second surface has a second implantation region, a second implantation dose of the second implantation region is between about 1×10¹⁰ #/cm² and about 5×10¹⁶ #/cm², and the second implantation dose is different from the first implantation dose.

17. The semiconductor wafer of claim 16, wherein an implant species in the second implantation region is different from an implant species in the first implantation region.

18. The semiconductor wafer of claim 12, wherein an implant species in the first implantation region comprises at least one of a titanium ion, a nickel ion, an iron ion, a zirconium ion, a tin ion, a magnesium ion, a cobalt ion, an arsenic ion, a zinc ion, an indium ion, an antimony ion, a germanium ion, a hydrogen ion, a helium ion, an oxygen ion, an aluminum ion, a boron ion, a nitrogen ion, a phosphorus ion, a silicon ion, and a carbon ion.
